(19) United States
(12) Patent Application Publication
(10) Pub. No.: US 2006/0028701 A1
(43) Pub. Date: Feb. 9, 2006

(54) Color image forming apparatus

(75) Inventor: Yuusuke Suzuki, Mishima-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 10/909,338

(22) Filed: Aug. 3, 2004

(51) Int. Cl. G03F 3/08

(52) U.S. Cl. 358/518

(57) ABSTRACT

A CPU of a printer controller analyzes PDL data that is sent from a PC, and generates intermediate codes for one page. After the completion of generation of intermediate codes for one page, the CPU reads out the intermediate codes one by one in the order of drawing, and executes an image forming process for an object. In this case, the CPU determines whether outline information of the drawing object is registered in a hard disk drive. If the outline information is registered in the hard disk drive, the CPU reads out the outline information from the hard disk drive. If not, the CPU computes the outline of the object. Using the obtained outline information, the CPU draws the object in the drawing process using a trapping scheme.

### BACKGROUND OF THE INVENTION

1. Field of the Invention

The present invention relates to a color image forming apparatus that forms an image by performing a proper image process, for example, using a trapping process for suppressing occurrence of a white gap due to print misregistration, when printing is executed by an electrophotographic color printer or the like.

2. Description of the Related Art

In the prior art, there is known a trapping process as a method for preventing print misregistration when an image is printed.

Jpn. Pat. Appln. KOKAI Publication No. 2000-232590 discloses a method for alleviating an effect of print misregistration on a peripheral region of a black object by adding a color material, other than black, to the entirety of the black object or to an edge part of the region of the black object.

Jpn. Pat. Appln. KOKAI Publication No. 2002-165104 discloses a method wherein a boundary between objects, which are to be subjected to a trapping process, is extracted, and a trapping region in the objects adjoining the boundary is determined, following which a trapping color for the trapping region is determined and the trapping region is painted with the trapping color.

The trapping process, however, requires a great deal of computations. This makes it difficult to carry out the trapping process in an inexpensive, low-speed printer using a low-speed CPU, or to achieve high-speed performance using software for a high-speed printer.

### BRIEF SUMMARY OF THE INVENTION

The object of an aspect of the present invention is to provide a color image forming apparatus capable of performing a high-speed computation of a trapping region, while maintaining the effect of a trapping process.

According to an aspect of the present invention, there is provided a color image forming apparatus that prints a color image by overlapping a plurality of color components, comprising: storage means for storing outline information of a drawing object that is to be subjected to a trapping process for suppressing occurrence of a white gap due to print misregistration; computation means for computing the outline information of the drawing object that is to be subjected to the trapping process; first determination means for determining whether the outline information of the drawing object is stored in the storage means, when the trapping process is executed; and process means for acquiring the outline information of the drawing object from the storage means in a case where the first determination means determines that the outline information of the drawing object is stored in the storage means, causing the computation means to compute the outline information of the drawing object in a case where the first determination means determines that the outline information of the drawing object is not stored in the storage means, and executing the trapping process using the acquired outline information or the computed outline information.

Additional objects and advantages of an aspect of the invention will be set forth in the description which follows, and in part will be obvious from the description, or may be learned by practice of the invention. The objects and advantages of an aspect of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of an aspect of the invention.

FIG. 1 is a block diagram that schematically shows the structure of a color image forming apparatus according to the present invention;

FIG. 2 is a timing chart relating to a first embodiment;

FIG. 3 is a flow chart illustrating an operation of an image forming process according to the first embodiment;

FIG. 4 is a timing chart relating to a second embodiment;

FIG. 5 is a timing chart relating to a fourth embodiment;

FIG. 6 shows an example of a user interface screen display;

FIG. 7 is a timing chart relating to a fifth embodiment;

FIG. 8 shows an example of a font download wizard screen display;

FIG. 9 is a flow chart illustrating an operation of an image forming process according to a sixth embodiment;

FIG. 10 is a view for explaining computations of object outlines in a trapping process according to a seventh embodiment;

FIG. 11 is a flow chart explaining the computations of object outlines in the trapping process according to the seventh embodiment;

FIG. 12 is a flow chart explaining computations of outline information in a trapping process relating to a ninth embodiment;

FIG. 13 shows an original image of a drawing object;

FIG. 14 shows an image that is obtained by a skeletonization image process;

FIG. 15 shows extracted outline information;

FIG. 16 is a flow chart explaining an outline information extraction computation in a trapping process relating to a tenth embodiment;

FIG. 17 shows a drawing character;

FIG. 18 shows a smaller-point font of the same kind;

FIG. 19 shows extracted outline information;

FIG. 20 is a flow chart explaining an outline information extraction process in a trapping process relating to an eleventh embodiment;

FIG. 21 shows an original image of a Gothic font;

FIG. 22 shows a Ming-style font, which is designed thinner than the Gothic font of the original image;

FIG. 23 shows extracted outline information;

FIG. 24 is a flow chart explaining an outline information extraction process in a trapping process relating to a twelfth embodiment;

FIG. 25 shows an original image;

FIG. 26 shows a result of division by triangles;

FIG. 27 illustrates triangle reduction;

FIG. 28 illustrates connection of apices;

FIG. 29 shows extracted outline information;

FIG. 30 is a flow chart explaining an outline information extraction process in a trapping process relating to a 13th embodiment;

FIG. 31 shows extracted outline information;

FIG. 32 is a flow chart explaining an outline information extraction process in a trapping process relating to a 14th embodiment;

FIG. 33 shows an original image;

FIG. 34 illustrates division by triangles;

FIG. 35 illustrates division by an apex thin-out process;

FIG. 36 is a flow chart explaining an outline information extraction process in a trapping process relating to a 15th embodiment;

FIG. 37 shows a print original;

FIG. 38 shows foreground drawing objects; and

FIG. 39 illustrates a trapping process.

### DETAILED DESCRIPTION OF THE INVENTION

Embodiments of the present invention will now be described with reference to the accompanying drawings.

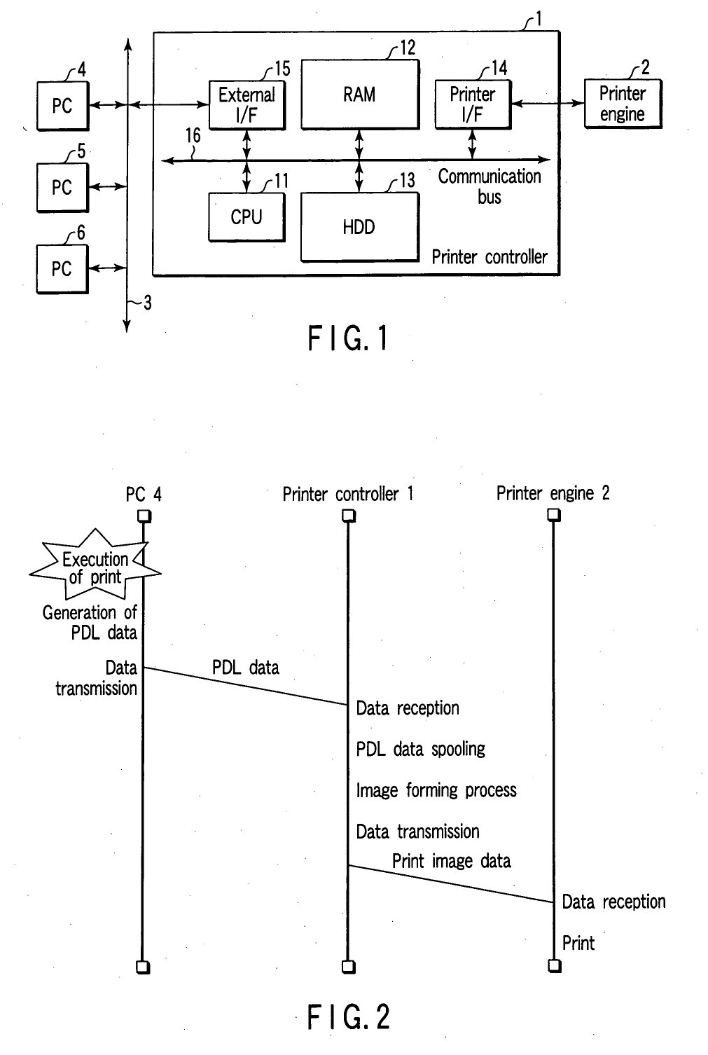

FIG. 1 schematically shows the structure of a color image forming apparatus according to the present invention. The color image forming apparatus comprises a printer controller 1 and a printer engine 2.

The printer engine 2 receives print image data that is produced by the printer controller 1, and prints out the received image data.

Personal computers (PC) 4, 5 and 6 are connected to the printer controller 1 via a network 3.

The PCs 4, 5 and 6 are communicable with the printer controller 1 via the network 3. Upon a print request from a user, the PC generates PDL data that is described in a printer description language, and transmits the PDL data to the printer controller 1.

The printer controller 1 comprises a CPU 11 that executes an overall control, a RAM 12 that temporarily stores data, a hard disk drive (HDD) 13, a printer interface (I/F) 14 that enables communication with the printer engine 2, an external interface (I/F) 15 that enables communication with the PC 4, 5, 6 via the network 3, and a communication bus 16 that is used for communication between the internal structural components.

The CPU 11, RAM 12, HDD 13, printer I/F 14 and external I/F 15 are connected to the communication bus 16.

The HDD 13 stores a program for executing an image forming process. This program is loaded in the RAM 12 and executed prior to a printing process. In the image forming process, PDL data that is spooled in an area in the HDD 13 is analyzed and image data for printing is generated.

Next, a first embodiment of the invention will be described.

Processing in the PC 4, printer controller 1 and printer engine 2 at a time of executing a print operation is explained referring to a timing chart of FIG. 2.

To begin with, on the PC 4, PDL data, which is print data for executing printing, is prepared by the user. The prepared PDL data is transmitted from the PC 4 to the printer controller 1 via the network 3.

The printer controller 1 receives the PDL data via the external I/F 15 and stores the PDL data in a spool area in the HDD 13.

The image forming process program, which is running on the CPU 11, retrieves the spooled PDL data from the HDD 13 and analyzes the PDL data. According to the description of the PDL data, print image data is generated.

The print image data is sent to the printer engine 2 via the printer I/F 14.

The printer engine 2 executes a print-out operation based on the received print image data.

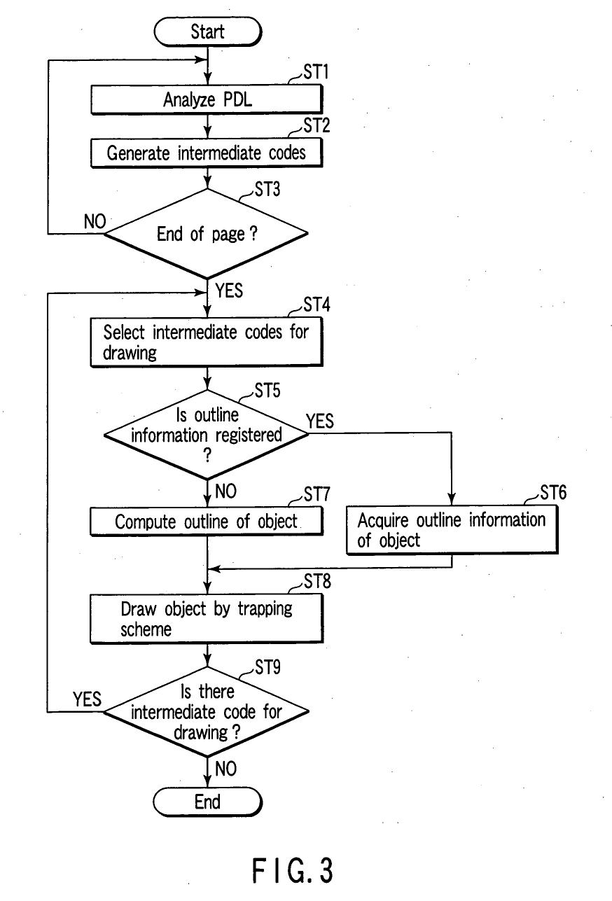

Referring now to a flow chart of FIG. 3, a description is given of the operation of the image forming process in the above-described structure.

The CPU 11 analyzes the PDL data (ST1) and generates intermediate codes for one page (ST2). The intermediate codes are data that are necessary for drawing objects.

After the completion of generation of intermediate codes for one page (ST3), the CPU 11 reads out the intermediate codes one by one in the order of drawing (ST4). Thus, the image forming process for an object is executed.

In this case, the CPU 11 determines whether outline information of a drawing object is registered in the HDD 13 in advance (ST5).

If the outline information is registered in step ST5, the CPU 11 reads out the outline information from the HDD 13 (ST6). If not, the CPU 11 computes the outline of the object (ST7).

Using the obtained outline information, the CPU 11 draws the object in the drawing process using a trapping scheme (ST8).

The CPU 11 repeats the process from the read-out of the intermediate codes (step ST4) to the drawing (ST8) until all the intermediate codes are read out (ST9).

The above-described series of process steps is repeated until all pages described in the PDL data are drawn. As regards some of the objects, the pre-computed outline information is used. Therefore, the trapping process can be executed at high speed.

The outline information in the first embodiment is subjected to an enlargement/reduction process when it is read out of the HDD 13, in accordance with the size of the object to be drawn.

In the first embodiment, possible examples of objects, whose outline information is pre-registered, are fonts such as characters or symbols, and graphics marks and logos.

In the above description, the PDL data is spooled in the HDD 13 in the printer controller 1. Alternatively, the PDL data may be stored in the memory, and the same advantageous effect is obtained.

The program for executing the image forming process may be stored not in the HDD 13, but in a ROM or a nonvolatile RAM.

The image forming process itself may be realized by hardware, as well as by the above-described program format, and the same advantageous effect is obtained.

Next, a second embodiment of the invention is described.

In the second embodiment, in addition to the first embodiment, outline information of a font is computed at a time of font download, and the outline information along with the font is stored in the HDD 13.

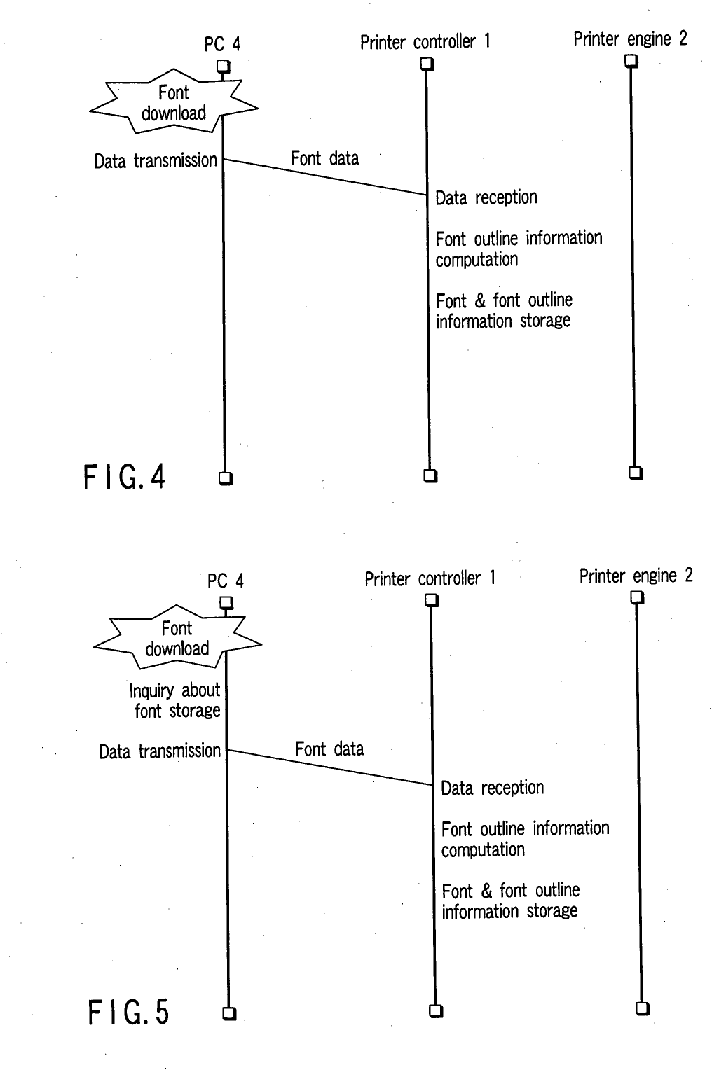

This process is described referring to a timing chart of FIG. 4.

To start with, when the user executes font download on the PC 4, the font data is transmitted from the PC 4 to the printer controller 1 via the network 3. The printer controller 1 receives the font data via the external I/F 15. In this case, the CPU 11 calculates font outline information at the same time, and stores the font outline information as well as the font data in the HDD 13.

The font outline information is used in the trapping process in the image forming process at the time of executing printing.

Next, a third embodiment is described.

In the third embodiment, in addition to the second embodiment, a font with a large number of apices is automatically determined at the time of font download, and only the outline information of the font with a large number of apices is stored in the HDD 13.

In the third embodiment, outline information of a font with a small number of apices, which tends to be less heavy in computation load than outline information of a font with a large number of apices, is computed at the time of executing the image forming process. Thereby, the area in the HDD 13, which is used for storage of the outline information, can be reduced.

Next, a fourth embodiment is described.

In the fourth embodiment, an inquiry about permission/non-permission of registration of font outline information is issued to the user in the technique of the second or third embodiment.

This process is described referring to a timing chart of FIG. 5.

To begin with, the user executes font download on the PC 4.

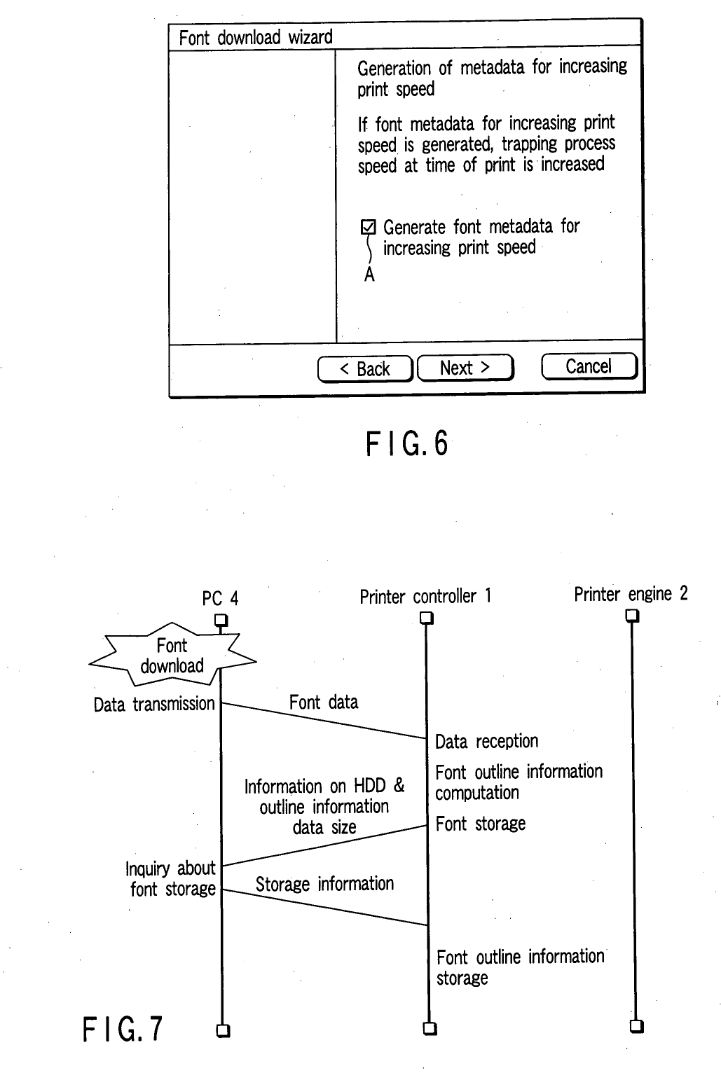

In this case, a user interface screen, as shown in FIG. 6, is displayed on the PC 4 at the timing of transmitting font data, and the user is asked about permission/non-permission of registration of font outline information.

If the user marks a check box A, it is determined that storage of outline information is permitted, and data transmission is executed. If the user does not mark the check box A, it is determined that storage of outline information is not permitted, and data transmission is executed.

The printer controller 1 receives font data via the external I/F 15.

In the case where the storage of outline information is permitted, the CPU 11 computes font outline information and stores the font outline information along with the font data in the HDD 13.

In the case where the storage of outline information is not permitted, the CPU 11 does not compute font outline information and stores only the received font data in the HDD 13.

Next, a fifth embodiment is described.

In the fifth embodiment, before asking the user, the outline information is computed and the data size for outline information storage is calculated. The user is notified of this information, and then the user is asked about the permission/non-permission.

This process is described referring to a timing chart of FIG. 7.

To start with, the user executes font download on the PC 4. The font data is transmitted from the PC 4 to the printer controller 1 via the network 3. The printer controller 1 receives the font data via the external I/F 15.

In this case, the CPU 11 computes font outline information from the received font data, and sends the information relating to the amount of use in the HDD 13 and the data size of the font outline information to the PC 4.

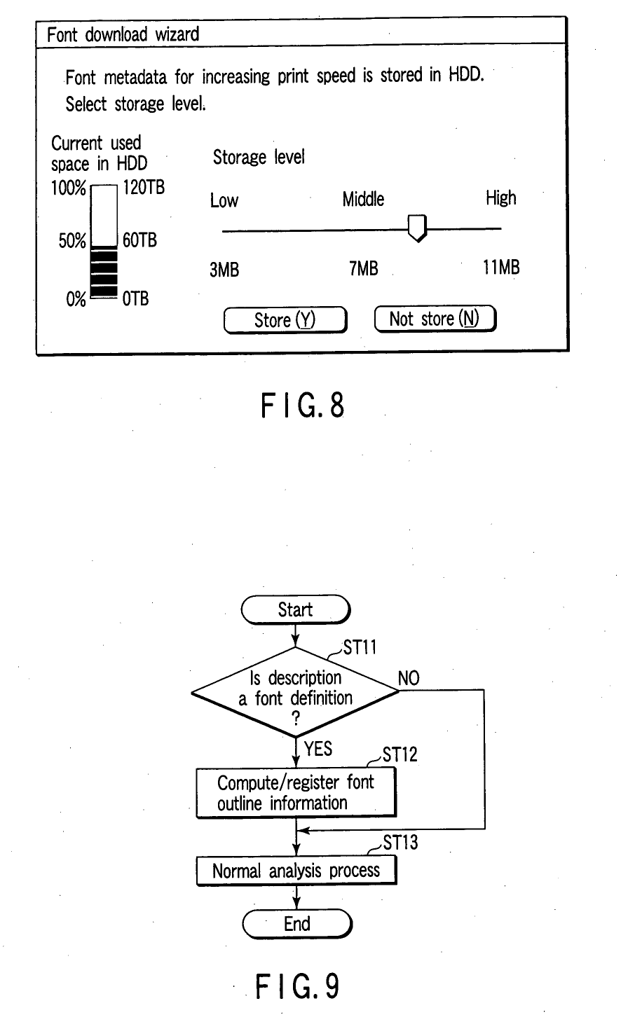

On the PC 4, the received information is displayed as “font download wizard” as shown in FIG. 8, and permission/non-permission of storage of font outline information is asked.

Storage information relating to the determination result on the permission/non-permission of storage of font outline information is sent from the PC 4 to the printer controller 1 via the network 3. The CPU 11 of the printer controller 1 receives the storage information via the external I/F 15.

If the storage information is indicative of permission of storage, the CPU 11 stores the font outline information in the HDD 13.

In the fifth embodiment, in addition to the structure of the fourth embodiment, the registration and use of the font outline information can be managed on a user-by-user basis.

Next, a sixth embodiment is described.

In the sixth embodiment, in addition to the structure of the first embodiment, font outline information is prepared in advance when font definition information that is described in the header part of the PDL data is analyzed, and the font outline information is used in the trapping-scheme drawing process.

The CPU 11 executes the process of analyzing the PDL in step ST1 in the first embodiment in the following manner.

The operation in the image forming process according to the present embodiment is described referring to a flow chart of FIG. 9.

To start with, the CPU 11 determines whether the description of PDL data is a font definition or not (ST11).

If the description of PDL data is a font definition, the CPU 11 executes a process for computing and registering font outline information (ST12).

If the description of PDL data is not a font definition, or following the processing in step ST12, the CPU 11 executes a normal analysis process (ST13).

If the PDL data includes a font definition description, as in the above case, it is possible to compute the outline information in advance at the time of analysis, and then to execute drawing. Thereby, there is no need to repeatedly perform outline information computations of the same character, in the print process of data in which a character that is defined in the header part of the PDL data is used several times in one page.

As a result, the image forming process can be performed at high speed.

Next, a seventh embodiment is described.

In the seventh embodiment, shifting of an image is utilized in the method of computing outline information in the trapping process.

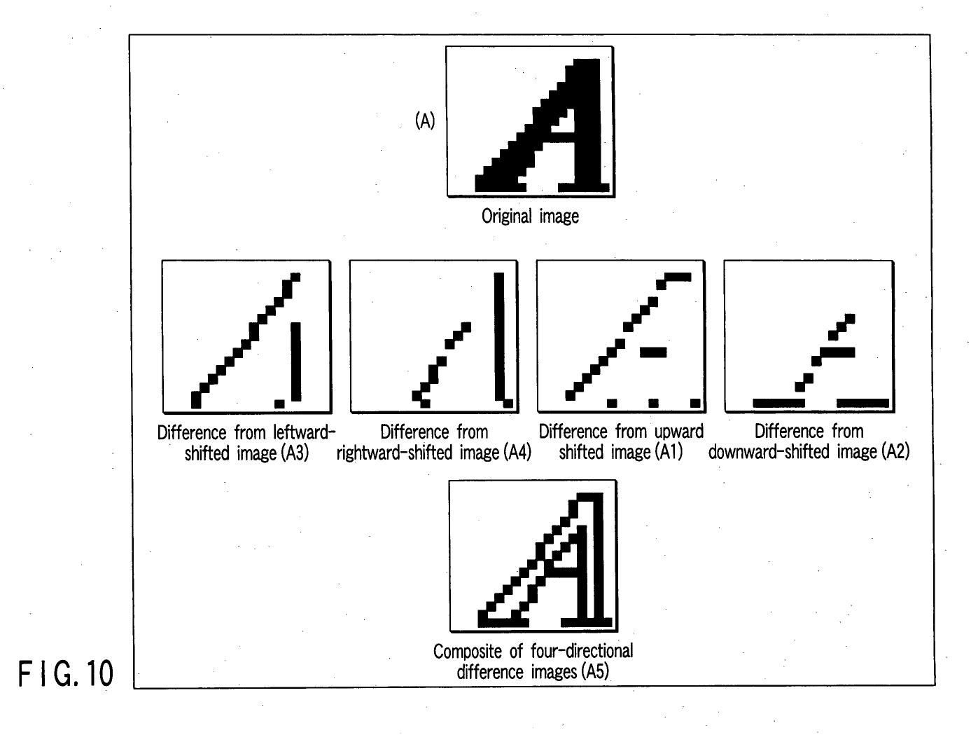

In the present embodiment, an object outline part is computed at the time of the trapping process, as illustrated in FIG. 10.

As shown in part (A) in FIG. 10, the CPU 11, the CPU 11 raster-develops a drawing object as an original image. Then, the CPU 11 forms images that are obtained by shifting the original image shown in part (A) of FIG. 10 upward, downward, leftward and rightward by predetermined numbers of pixels. The shifted images are overlapped with the original image, and pixels corresponding to different parts, which are present only in the shifted images, are extracted. Then, the CPU 11 shifts the images of the four-directional different parts in directions opposite to the directions of the initial shifts by the same degrees, thereby restoring the shifted images to the original position.

Part (A1) of FIG. 10 shows an image corresponding to a difference from the upward-shifted image, part (A2) of FIG. 10 shows an image corresponding to a difference from the downward-shifted image, part (A3) of FIG. 10 shows an image corresponding to a difference from the leftward-shifted image, and part (A4) of FIG. 10 shows an image corresponding to a difference from the rightward-shifted image.

The CPU 11 overlaps these four different-part images and produces object outline information, as shown in part (A5) of FIG. 10.

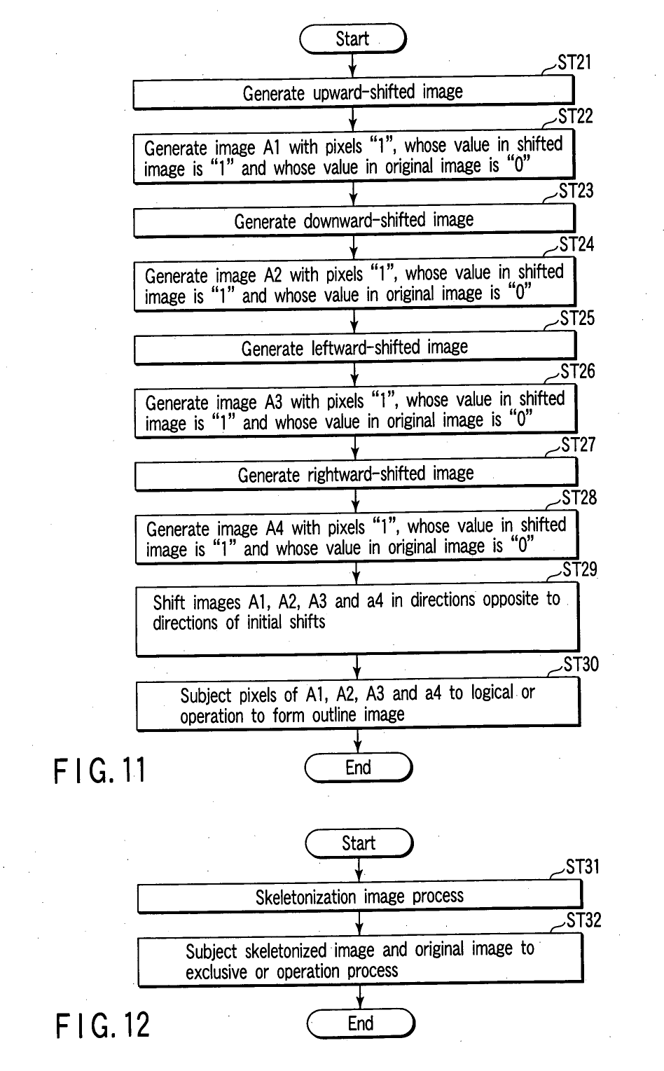

Next, the computation of the object outline parts in the above-described trapping process is described referring to a flow chart of FIG. 11.

The CPU 11 first forms an image that is obtained by shifting the original image upward by a predetermined number of pixels (ST21). The CPU 11 then forms an image A1 that has pixels “1”, whose value in the sifted image is “1” and whose value in the original image is “0” (ST22).

Subsequently, the CPU 11 forms an image that is obtained by shifting the original image downward by a predetermined number of pixels (ST23). The CPU 11 then forms an image A2 that has pixels “1”, whose value in the sifted image is “1” and whose value in the original image is “0” (ST24).

Further, the CPU 11 forms an image that is obtained by shifting the original image leftward by a predetermined number of pixels (ST25). The CPU 11 then forms an image A3 that has pixels “1”, whose value in the sifted image is “1” and whose value in the original image is “0” (ST26).

Subsequently, the CPU 11 forms an image that is obtained by shifting the original image rightward by a predetermined number of pixels (ST27). The CPU 11 then forms an image A4 that has pixels “1”, whose value in the sifted image is “1” and whose value in the original image is “0” (ST28).

Following the above, the CPU 11 shifts the images A1, A2, A3 and A4 in direction opposite to the directions of the initial shifts (ST29).

At last, the CPU 11 subjects the pixels of the images A1, A2, A3 and A4 to a logical OR operation, thereby forming an outline image A5 (ST30).

As has been described above, in the seventh embodiment, the rasterized image is uniformly subjected to the process. Thus, the trapping process can be similarly applied to any kind of object, regardless of the description format.

Next, an eighth embodiment is described.

In the eighth embodiment, the shifting is not executed in all directions when the trapping outline is formed in the structure of the seventh embodiment.

There is a case where print misregistration may occur only in a certain direction due to non-uniformity among devices with respect to the mechanism of the printer engine 2.

The eighth embodiment is particularly effective for such misregistration. The outline, which is obtained by the shift in the direction of misregistration, is utilized.

Therefore, while the same advantageous effect as with the seventh embodiment is obtained, the time for the computation process and the amount of toner can be reduced.

Next, a ninth embodiment is described.

In the ninth embodiment, skeletonization is applied to the image process when the outline information is computed in the trapping process.

The outline information computation in the trapping process is described referring to a flow chart of FIG. 12.

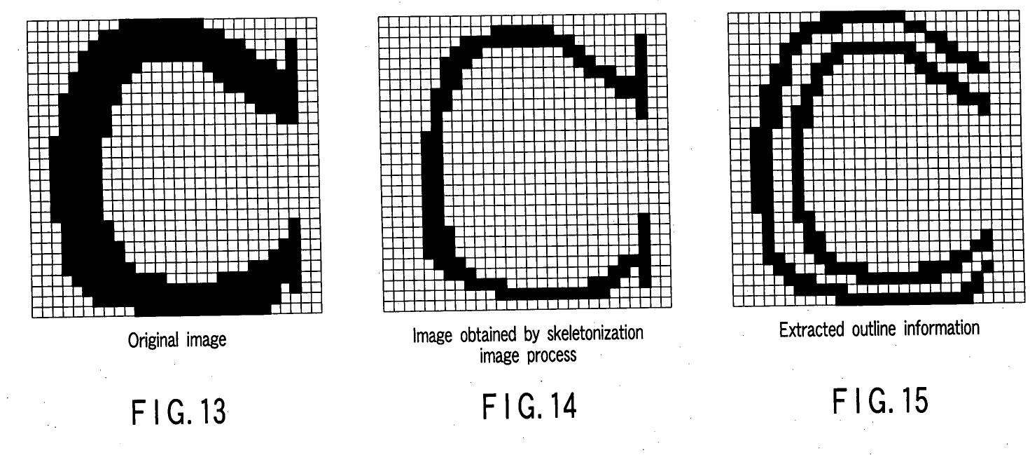

To start with, the CPU 11 executes a skeletonization image process on the original image of a drawing object shown in FIG. 13 (ST31). FIG. 14 shows an image obtained by the skeletonization image process.

Then, the CPU 11 subjects the skeletonized image and the original image to an exclusive-OR process (ST32).

Specifically, the CPU 11 overlaps the original image and the skeletonized image, and extracts pixels that are present only in the original image. Thus, outline information as shown in FIG. 15 is obtained.

The CPU 11 executes a trapping-scheme drawing process, using the extracted outline information as the outline part of the original image.

Next, a tenth embodiment is described.

In the tenth embodiment, when outline information of a font object is computed in the trapping process, a font, which is of the same kind as the font to be drawn and has a smaller point number than the font to be drawn, is utilized.

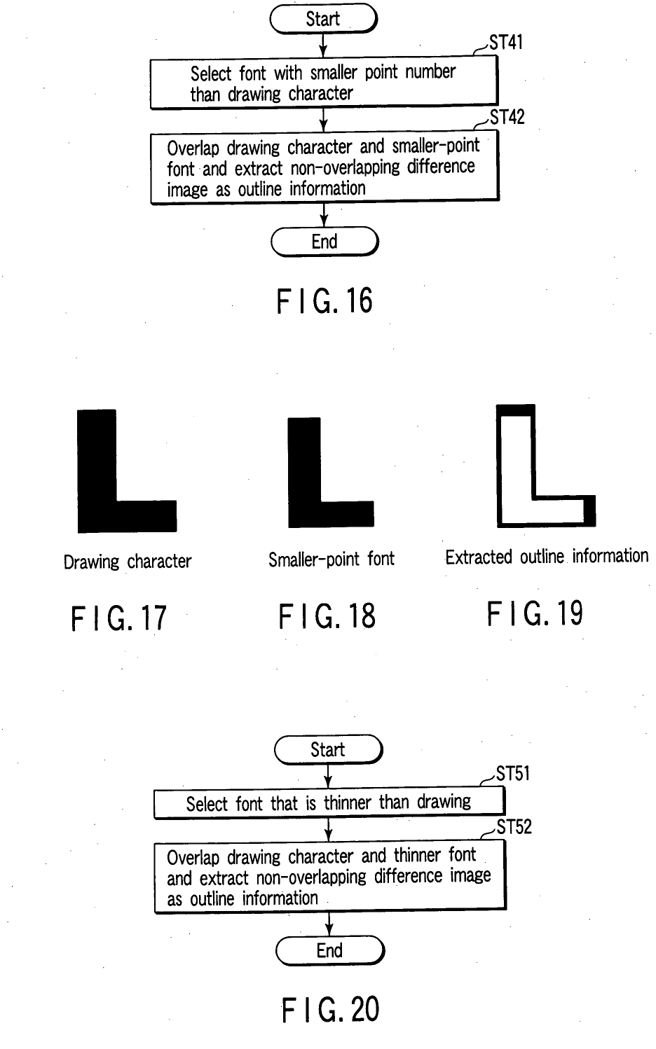

The outline information computation in the trapping process is described referring to a flow chart of FIG. 16.

To start with, the CPU 11 selects a font (of the same kind) with a smaller point number than a font to be drawn shown in FIG. 17 (ST41). FIG. 18 shows the smaller-point font of the same kind.

Subsequently, the CPU 11 overlaps the font to be drawn shown in FIG. 17 and the smaller-point font, and extracts an image corresponding to a non-overlapping difference part as outline information (ST42). FIG. 19 shows the extracted outline information.

The CPU 11 executes the trapping-scheme drawing process, using the extracted outline information as the outline part of the original image.

Next, an eleventh embodiment is described.

In the eleventh embodiment, when outline information of a font object is computed in the trapping process, a font, which is designed thinner than the font to be drawn, is utilized.

The outline information computation in the trapping process is described referring to a flow chart of FIG. 20.

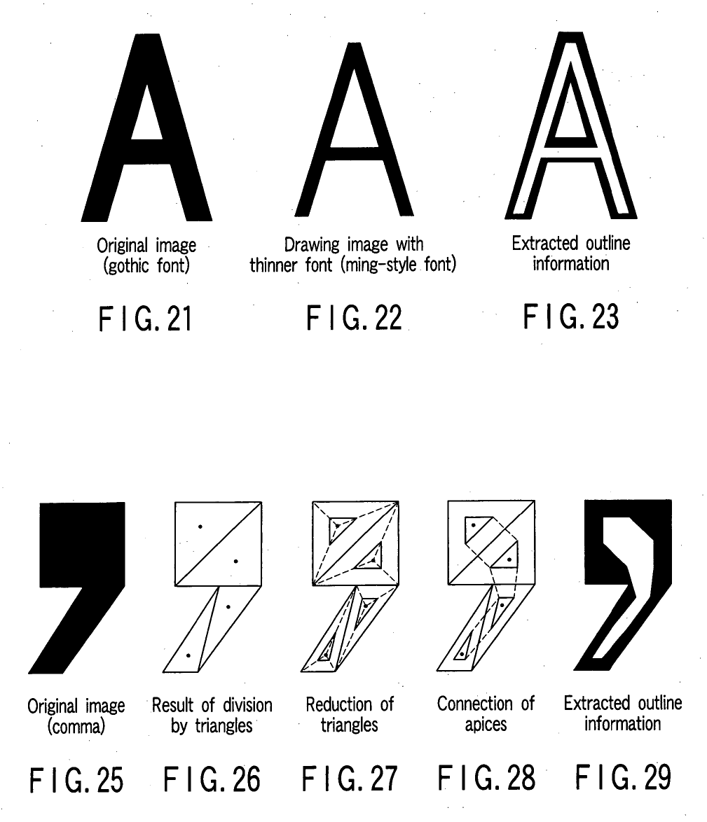

To start with, the CPU 11 selects a thin font that is designed thinner than the font of an original image shown in FIG. 21 (ST51). FIG. 22 shows a Ming-style font, which is designed thinner than the Gothic font of the original image.

Subsequently, the CPU 11 overlaps the original image shown in FIG. 21 and the thin font, and extracts an image corresponding to a non-overlapping different part as outline information (ST52). FIG. 23 shows the extracted outline information.

The CPU 11 executes the trapping-scheme drawing process, using the extracted outline information.

It is assumed that information indicative of presence/absence of a font that is thinner than a specified font is registered prior to the print process.

Next, a twelfth embodiment is described.

The twelfth embodiment relates to an outline information extraction method in a trapping process for graphics or fonts, which are expressed in a format that can be developed on coordinates such as vector coordinates.

In this embodiment, when coordinates/vector-format graphics or fonts are to be drawn in the trapping-scheme outline extraction process, outline information is extracted by making use of division into triangles.

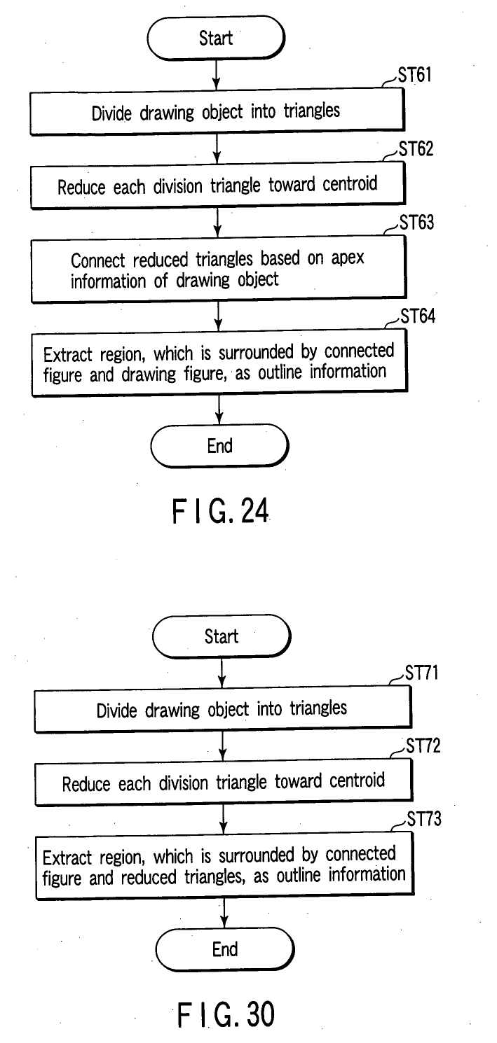

The trapping-scheme outline information extraction process is described referring to a flow chart of FIG. 24.

To begin with, the CPU 11 divides the drawing object of an original image shown in FIG. 25 by triangles, using apex information relating to apices of the drawing object (ST61). FIG. 26 shows a result of the division by triangles.

Then, the CPU 11 reduces each divisional triangle toward its centroid (ST62), and connects the apices on the basis of the relationship of adjoining between the triangles in the pre-reduction state (ST63). FIG. 27 shows the state in which each triangle is reduced toward its centroid, and FIG. 28 shows the state in which the apices of the triangles are connected.

Finally, the CPU 11 overlaps the figure, which is formed by connecting the triangles, and the original image, and extracts a figure, which corresponds to a non-overlapping part, as outline information (ST64). FIG. 29 shows the extracted outline information.

The CPU 11 executes the image forming process by the trapping process, using the extracted outline information.

In the outline information extraction process in this embodiment, the division triangles are reduced towards their centroids. Therefore, an outline that is closer to the figure of the object can be extracted.

Next, a 13th embodiment is described.

In the 13th embodiment, the process of connecting the reduced triangles is omitted in the outline extraction computation method of the twelfth embodiment, thereby realizing a high-speed process.

This outline information extraction process using the trapping scheme is described referring to a flow chart of FIG. 30.

Steps ST71 and ST72 are the same as steps ST61 and ST62 in the twelfth embodiment, so a description thereof is omitted. The process steps illustrated in FIG. 25 to FIG. 27 are also the same.

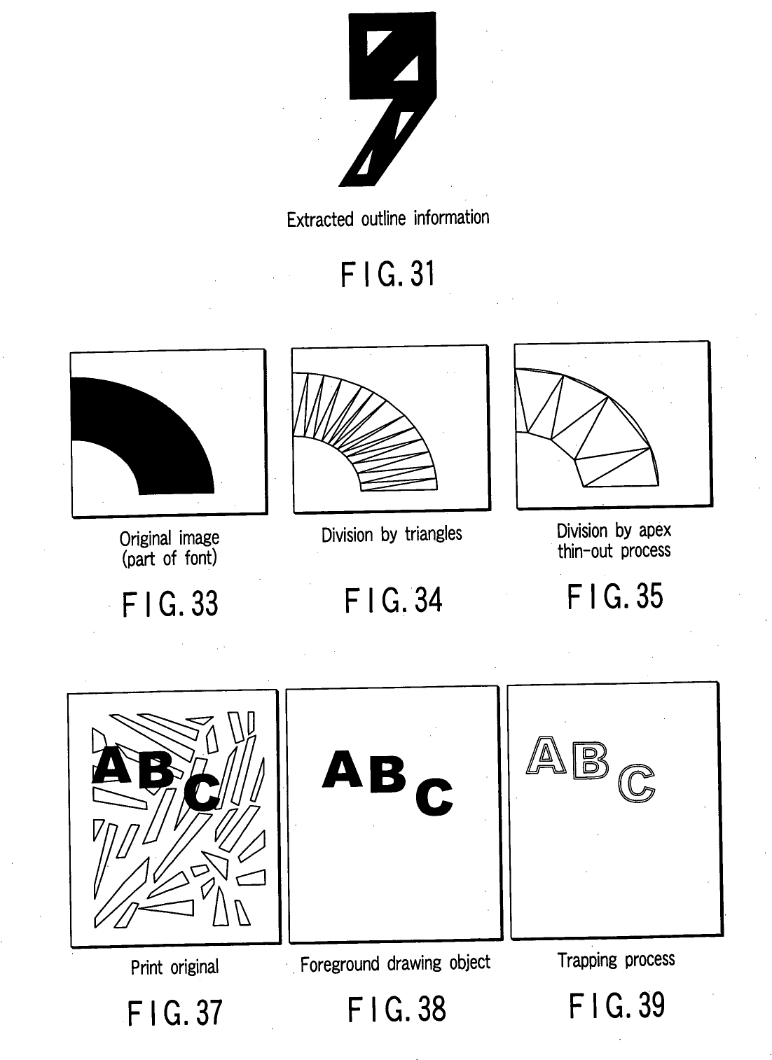

Following step ST72, the CPU 11 overlaps the reduced triangles and the original image, thereby extracting a figure corresponding to a non-overlapping different part as outline information (ST73). FIG. 31 shows the extracted outline information.

In the 13th embodiment, the outline information is less accurate than in the twelfth embodiment, but the amount of computations is smaller and a high-speed process is realized.

Next, a 14th embodiment is described.

The 14th embodiment adopts the trapping process according to the twelfth embodiment or 13th embodiment, wherein the division of the object by triangles is utilized.

In the 14th embodiment, when the graphic object is divided by triangles on the basis of information on apices, the division by triangles is executed by omitting parts where apices, at which obtuse angles are formed between adjoining line segments, are successively located.

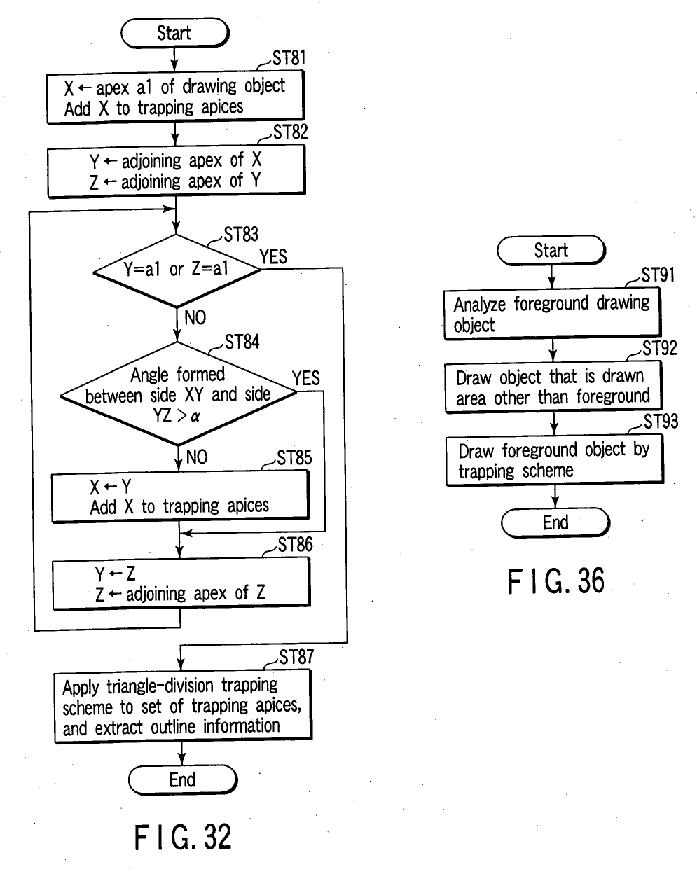

This outline information extraction process using the trapping scheme is described referring to a flow chart of FIG. 32.

The CPU 11 takes an apex a1 of a drawing object as “X”, and adds “X” to trapping apices (ST81).

The CPU 11 takes an apex adjacent to “X” as “Y”, and takes an apex adjacent to “Y” as “Z” (ST82).

The CPU 11 determines whether Y=a1, or Z=a1 (ST83).

If it is not determined in step ST82 that Y=a1 or Z=a1, the CPU 11 then determines whether the angle formed between a side XY and a side YZ is greater than a predetermined angle α (ST84).

If the formed angle is equal to or less than the predetermined angle α in step ST84, “Y” is changed to “X”, and “X” is added to trapping apices (ST85).

Following step ST85, or if the formed angle is greater than the predetermined angle α in step ST84, “Z” is set to be “Y”, and “Z” is set to be an adjacent apex of “Z” (ST86), and the control returns to step ST83.

If Y a1 or Z=a1 in step ST83, the CPU 11 applies the triangle-division trapping scheme to the set of trapping apices, thereby extracting outline information (ST87).

For example, when a font as shown in FIG. 33 is to be drawn, a triangle-division process is executed using the coordinates of the font, and the font is divided into a great number of triangles, as shown in FIG. 34.

In the 14th embodiment, as shown in FIG. 35, apices at parts where the angle of outline parts are obtuse angles are omitted when the triangle-division process is performed. Thereby, the object can be divided by a less number of triangles, and a high-speed process can be performed.

Next, a 15th embodiment is described.

In the 15th embodiment, a drawing process is performed while information of a foreground drawing object is being saved, and after formation of print image data, the saved drawing object is drawn once again by a trapping scheme.

This outline information extraction process using the trapping scheme is described referring to a flow chart of FIG. 36.

To begin with, the CPU 11 analyzes a foreground drawn object (ST91). FIG. 37 shows an example of a print original.

The CPU 11 then draws an object that is drawn on an area other than the foreground (ST92). FIG. 38 shows an example of the foreground drawn object.

The CPU 11 draws the foreground object by the trapping scheme (ST93). FIG. 39 shows an example of the trapping process.

Next, a 16th embodiment is described.

The 16th embodiment has a function of performing an image forming process using both drawing schemes of an overprint scheme and a trapping scheme. The image formation by these schemes can be switched for individual drawing objects.

In the 16th embodiment, when the size of a drawing object is determined to be less than a threshold value, the object is drawn by the overprint scheme. Otherwise, the object is drawn by the trapping scheme.

In many cases, a computation process can be performed at a higher speed in the overprint-scheme drawing process than in the trapping-scheme drawing process. In the case where the size of a drawing object is small, the shape of an object outline part may substantially be equal to that of the object itself, depending on a trapping amount (i.e. a width of an object outline part that is overlapped with a background image). Even where the object is drawn by the overprint scheme or by the trapping scheme, the part that is overlapped with the background image may hardly change, and substantially the same effect is obtained.

For the above reason, in the present embodiment, with respect to an object with a small drawing size, it is possible to realize substantially the same effect of a misregistration prevention measure as in the prior-art trapping scheme, while realizing a high-speed process.

In an example of the method of determining the drawing object size in the present embodiment, the size may be computed from the coordinates information of the drawing object and the reduction scale in the scaling process.

Another available method is to count the number of pixels of the object to be drawn, by rasterizing the drawing object on the memory.

If the drawing object is not a character, the size is determined by one of these two size determination methods.

In the case of characters, character codes of characters with small drawing areas, such as “,” and “.” are registered. If the character code of a drawing object is included in these codes, the object is determined to have a small size. Otherwise, the object is determined to have a large size.

As has been described above, according to the embodiments of the invention, pre-registered outline information of a drawing object is utilized as trapping area information in the trapping process. Thereby, the image forming process can be performed at high speed.

In addition, at the time of the font download in the printer controller, font outline information is prepared and stored for utilization. Thereby, the character drawing process in the image forming process can be performed at high speed. Furthermore, at the time of the font download, fonts, whose outline information is to be registered, is selected on the basis of the number of apices of the fonts. Thereby, character drawing can be performed at high speed with a small memory area.

At the time of the font download, an inquiry about permission/non-permission of registration of outline information is issued to the user. It thus becomes possible to prevent wasteful use of the memory area by storing outline information of fonts with less frequency of use.

When the font definition part in the header of the PDL file is analyzed, the font outline information is prepared in advance and utilized. Thereby, the number of times of preparation of outline information can be reduced, and a high-speed process is realized.

After a drawing object is rasterized and developed into an image, a trapping area is computed using images that are obtained shifting the rasterized image. Thereby, the trapping area can be computed regardless of the description format of the drawing object.

In the method wherein the rasterized image is shifted and the trapping area is computed, the shifting is effected only in the direction in which print misregistration occurs. Thereby, the time for the trapping area computation process can be reduced, and the amount of toner that is consumed for the trapping process part can be saved.

The rasterized font is subjected to the skeletonization process and the skeletonized image is used as a trapping area. Thereby, the time for the trapping area computation can be performed in a predetermined time period, regardless of the font format.

A font with a smaller point number than a font to be drawn is used to compute a trapping area. Thereby, images of many kinds of fonts can be formed at high speed.

A font that is thinner than a font to be drawn is used to compute a trapping area. Thereby, the trapping area can be computed with high precision.

When an object that is composed of regions defined by connecting plural apices is to be drawn, the object is divided into triangles, thereby to compute outline information. This prevents a central part of a character or graphics from being treated as an outline.

In the method wherein the triangles are used to generate outline information, the process of connecting the triangles may be omitted. Thereby, the image forming process can be performed without losing the trapping effect.

Information of a foreground drawing object is saved, and after formation of print image data, the saved drawing object is drawn once again by a trapping scheme. Thereby, the time for executing a trapping process for an object, which is drawn on a background of another object and requires no trapping process, can be saved, and the high-speed image formation is realized.

An object with a small drawing area is subjected to the overprint process, and other objects are subjected to the trapping process. By performing the image forming process in this manner, it becomes possible to perform a high-speed process while obtaining substantially the same misregistration prevention effect as in the case where the entire objects are drawn by the trapping process.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A color image forming apparatus that prints a color image by overlapping a plurality of color components, comprising:
storage means for storing outline information of a drawing object that is to be subjected to a trapping process for suppressing occurrence of a white gap due to print misregistration;
computation means for computing the outline information of the drawing object that is to be subjected to the trapping process;
first determination means for determining whether the outline information of the drawing object is stored in the storage means, when the trapping process is executed; and
process means for acquiring the outline information of the drawing object from the storage means in a case where the first determination means determines that the outline information of the drawing object is stored in the storage means, causing the computation means to compute the outline information of the drawing object in a case where the first determination means determines that the outline information of the drawing object is not stored in the storage means, and executing the trapping process using the acquired outline information or the computed outline information.

2. The color image forming apparatus according to claim 1, further comprising reception means for receiving font data from outside, and first control means for effecting a control to cause the computation means to compute outline information of the font received by the reception means and to cause the storage means to store the computed font outline information and the font data.

3. The color image forming apparatus according to claim 1, further comprising reception means for receiving font data from outside, and second control means for effecting a control to determine a font with a number of apices of the font data received by the reception means, to cause the computation means to compute only outline information of the font with the number of apices, and to cause the storage means to store the computed font outline information and the font data.

4. The color image forming apparatus according to claim 1, further comprising reception means for receiving font data from outside, determination means for determining whether font outline information corresponding to the font data received by the reception means is to be stored, and third control means for effecting, when the determination means determines that the font outline information corresponding to the font data received by the reception means is to be stored, a control to cause the computation means to compute the font outline information corresponding to the font data and to cause the storage means to store the computed font outline information and the font data, and for effecting, when the determination means determines that the font outline information corresponding to the font data received by the reception means is not to be stored, a control to cause the storage means to store only the font data.

5. The color image forming apparatus according to claim 1, further comprising management means for managing storage of font outline information in the storage means and acquisition of font outline information from the storage means on a user-by-user basis.

6. The color image forming apparatus according to claim 1, further comprising second determination means for determining whether a description of PDL data is a font definition, and analysis process means for causing, when the second determination means determines that the description of PDL data is a font definition, the computation means to compute font outline information and causing the storage means to store the computed font outline information, and executing an analysis process for the PDL data after the storage of the computed font outline information or when the second determination means determines that the description of PDL data is not a font definition.

7. The color image forming apparatus according to claim 1, wherein the computation means subjects the drawing object, such as a font object or a graphics object, to a rasterizing process, prepares four shift images that are obtained by shifting the rasterized image upward, downward, leftward and rightward by predetermined numbers of pixels, and produces outline information of the drawing object by gathering only pixels at which the four shift images do not overlap the rasterized image.

8. The color image forming apparatus according to claim 1, wherein the computation means subjects the drawing object, such as a font object or a graphics object, to a rasterizing process, prepares a shift image that is obtained by shifting the rasterized image only in a selected direction of upward, downward, leftward and rightward directions by a predetermined number of pixels, and produces outline information of the drawing object by gathering only pixels at which the shift image does not overlap the rasterized image.

9. The color image forming apparatus according to claim 1, wherein the computation means subjects the drawing object, such as a font object or a graphics object, to a rasterizing process, and produces outline information by applying a skeletonization image process to the rasterized image.

10. The color image forming apparatus according to claim 1, wherein the computation means overlaps, when font drawing is executed, a font to be drawn and a font that is of the same kind as the font to be drawn and has a smaller point number than the font to be drawn, and produces outline information of the drawing object on the basis of a non-overlapping part.

11. The color image forming apparatus according to claim 1, wherein the computation means overlaps, when font drawing is executed, a font to be drawn and a font that is thinner than the font to be drawn, and produces outline information of the drawing object on the basis of a non-overlapping part.

12. The color image forming apparatus according to claim 1, wherein the computation means divides, when vector-format font drawing is executed, a font into a plurality of triangles using apex coordinates of the font, reduces each of the division triangles toward a centroid thereof, overlaps said font with a figure obtained by connecting apices of the reduced triangles on the basis of the relationship of adjoining between the triangles in the pre-reduction state, and produces outline information of the font on the basis of a figure corresponding to a non-overlapping part.

13. The color image forming apparatus according to claim 1, wherein the computation means divides, when vector-format font drawing is executed, a font into a plurality of triangles using apex coordinates of the font, reduces each of the division triangles toward a centroid thereof, overlaps said font with the reduced triangles, and produces outline information of the font on the basis of a figure corresponding to a non-overlapping part.

14. The color image forming apparatus according to claim 12, wherein the computation means divides, when vector-format font drawing is executed, a font into a plurality of triangles using apex coordinates of the font, compares an angle formed between adjoining sides with a predetermined angle, and, if the formed angle is greater, executes the division by triangles by omitting the apices that forms the angle.

15. A color image forming apparatus that prints a color image by suppressing occurrence of a white gap due to print misregistration, when the color image is printed by overlapping a plurality of color components, comprising:
analysis means for analyzing PDL data;
first control means for controlling generation of print image data while storing object information of a foreground drawing object on the basis of an analysis result of the analysis means; and
second control means for controlling an overwrite process by applying a trapping process to the print image data generated by the control of the first control means, on the basis of the stored object information.

16. The color image forming apparatus according to claim 15, further comprising determination means for determining whether a size of the drawing object is less than a predetermined threshold value, and control means for drawing, when the determination means determines that the size of the drawing object is less than the predetermined threshold value, the drawing object by an overprint scheme, and drawing, when the determination means determines that the size of the drawing object is equal to or greater than the predetermined threshold value, the drawing object by a trapping scheme.

17. A program for causing a color image forming apparatus, which prints a color image by overlapping a plurality of color components, to realize:
a storage function for storing outline information of a drawing object that is to be subjected to a trapping process for suppressing occurrence of a white gap due to print misregistration;
a computation function for computing the outline information of the drawing object that is to be subjected to the trapping process;
a determination function for determining whether the outline information of the drawing object is stored in the storage function, when the trapping process is executed; and
a process function for acquiring the outline information of the drawing object from the storage function in a case where the determination function determines that the outline information of the drawing object is stored in the storage function, causing the computation function to compute the outline information of the drawing object in a case where the determination function determines that the outline information of the drawing object is not stored in the storage function, and executing the trapping process using the acquired outline information or the computed outline information.

18. A program for causing a color image forming apparatus, which prints a color image by suppressing occurrence of a white gap due to print misregistration when the color image is printed by overlapping a plurality of color components, to realize:
an analysis function for analyzing PDL data;
a first control function for controlling generation of print image data while storing object information of a foreground drawing object on the basis of an analysis result of the analysis function; and
a second control function for controlling an overwrite process by applying a trapping process to the print image data generated by the control of the first control function, on the basis of the stored object information.
